(19) United States
(12) Patent Application Publication
(10) Pub. No.: US 2026/0184835 A1
(43) Pub. Date: Jul. 2, 2026

(54) RESIN COMPOSITION, PREPREG, RESIN FILM, METAL-CLAD LAMINATE, PRINTED WIRING BOARD, AND SEMICONDUCTOR PACKAGE

(71) Applicant: Resonac Corporation, Tokyo (JP)

(72) Inventors: Shinichiro ABE, Tokyo (JP); Yuji MATO, Tokyo (JP); Yusuke SERA, Tokyo (JP); Ai YOKOKURA, Tokyo (JP); Daisuke FUJIMOTO, Tokyo (JP); Tomohiko KOTAKE, Tokyo (JP); Toshikatsu SHIMAZAKI, Tokyo (JP)

(21) Appl. No.: 18/860,954

(22) PCT Filed: May 22, 2024
(86) PCT No.: PCT/JP2024/018831

§ 371 Date: Oct. 28, 2024

(30) Foreign Application Priority Data
May 24, 2023 (JP) 2023-085360

(51) Int. Cl. C08F 257/02; C08J 5/18; C08J 5/24; C08K 3/013; H05K 1/03

(52) U.S. Cl. CPC C08F 257/02; C08J 5/18; C08J 5/249; C08K 3/013; H05K 1/0373; C08J 2325/06; H05K 2201/0209

(57) ABSTRACT

A resin composition containing a curable prepolymer which contains a vinylbenzyl group and an indene ring and has a weight average molecular weight of 50,000 or higher. Also provided is a prepreg, a resin film, a metal-clad laminate, a printed wiring board and a semiconductor package obtained using the resin composition.

### TECHNICAL FIELD

The present invention relates to a resin composition, a prepreg, a resin film, a metal-clad laminate, a printed wiring board, and a semiconductor package.

### BACKGROUND ART

Metal-clad laminates typified by copper-clad laminates, prepregs that can be used in metal-clad laminates, and semiconductor packages that use metal-clad laminates are used in a wide variety of electronic devices, including mobile communication devices such as smart phones, network infrastructure equipment for such devices such as base station equipment, servers, routers and large-scale servers, as well as large computers, personal computers and industrial computers and the like. Further, they are also used in electronic equipment installed in household electric appliances and vehicles and the like. Among these uses, electronic communication devices are seeing increased demands for processing enormous amounts of data at high speed due to the growth of 5G.

In an electronic device, when a large amount of data must be processed at high speed, a substrate material that exhibits little transmission loss in the high frequency region is required. Substrates with low transmission loss using a resin with a low dielectric constant and a low dielectric loss tangent as the substrate material have been provided, but developments in communication technology in recent years mean that the development of resins of even lower dielectric constant and lower dielectric loss tangent is now required.

Patent Document 1 discloses a thermosetting resin composition containing a vinylbenzyl-based compound and a polycarbodiimide compound for use as a material for electronic componentry used in high frequency bands, and discloses that the obtained electronic components exhibit improved adhesion to metal materials while maintaining excellent dielectric characteristics.

### CITATION LIST

### Patent Document

Patent Document 1: JP 2007-119531 A

### SUMMARY OF THE INVENTION

### Technical Problem

In electronic devices and the like including mobile communication devices typified by smart phones, network infrastructure equipment for such devices such as base station equipment, servers and routers, and other electronic equipment such as large computers, the speed and capacity of the signals used continue to increase year by year. As a result, the printed wiring boards mounted in these electronic devices must be compatible with high frequencies, and require dielectric characteristics capable of reducing transmission loss, meaning substrate materials and the like having a low dielectric constant and a low dielectric loss tangent are required.

Patent Document 1 discloses a resin composition containing a vinylbenzyl-based compound and a polycarbodiimide compound, the composition having dielectric characteristics suited to high frequency band applications. However, investigations by the inventors of the present invention revealed that when a plurality of prepregs or resin films or the like formed using a resin composition containing this type of vinylbenzyl-based compound are overlaid on one another, they tend to bond together and become difficult to peel apart. Consequently, there is a possibility of a deterioration in workability during transport of the prepregs or the like or during production of metal-clad laminates. Further, the moldability of the resulting metal-clad laminates also leaves room for improvement.

The present invention has the objects of providing a resin composition that improves the tack properties of coated items and the moldability of cured products, and a prepreg, a resin film, a metal-clad laminate, a printed wiring board and a semiconductor package that use this resin composition.

### Solution to Problem

The present invention includes the following embodiment. However, the present invention is not limited to the embodiment described below.

One embodiment relates to a resin composition containing a curable prepolymer which contains a vinylbenzyl group and an indene ring and has a weight average molecular weight of 50,000 or higher.

### Advantageous Effects of Invention

The present invention is able to provide a resin composition that improves the tack properties of coated items and the moldability of cured products, as well as a prepreg, a resin film, a metal-clad laminate, a printed wiring board and a semiconductor package that use this resin composition.

### DETAILED DESCRIPTION OF THE EMBODIMENTS

Embodiments of the present invention are described below in detail. However, the present invention is not limited to the embodiments described below.

In this description, numerical ranges indicated using the expression “a to b” indicate a range that includes the numerical values before and after the “to” as the minimum value and maximum value respectively. In the case of numerical ranges listed in a stepwise manner in this description, the upper limit value or lower limit value from any particular numerical range may be arbitrarily combined with the upper limit value or lower limit value from another numerical range. In a numerical range disclosed in this description, the upper limit value or lower limit value from the numerical range may be used to replace a value shown in an example. In this description, unless specifically stated otherwise, each component may be composed of a single substance or two or more substances. In this description, the amount of each component in a resin composition, in the case where a plurality of substances corresponding with that component exist in the resin composition, unless specifically stated otherwise, means the total amount of the plurality of substances that exist in the resin composition.

In this description, unless specifically stated otherwise, weight average molecular weight (Mw) and number average molecular weight (Mn) values represent numerical values measured using the following procedure. The weight average molecular weight and number average molecular weight values were determined using gel permeation chromatography (GPC), from a calibration curve produced using standard polystyrenes. The calibration curve was approximated as a cubic equation using a 5-sample set of standard polystyrenes (PStQuick MP-H, PStQuick B [product names, manufactured by Tosoh Corporation]). The GPC conditions are shown below.
Apparatus: high-speed GPC device HLC-8320GPC (product name, Tosoh Corporation)
Detector: ultraviolet absorption detector UV-8320 (product name, Tosoh Corporation)
Columns: guard column: TSKgel guard column Super (HZ)-M+, columns: TSKgel SuperMultipore HZ-M (two columns), reference columns: TSKgel SuperH-RC (two columns), (all product names from Tosoh Corporation)
Column sizes: 4.6× 20 mm (guard column), 4.6×150 mm (columns), 6.0× 150 mm (reference columns)
Eluent: tetrahydrofuran
Sample concentration: 10 mg/mL
Injection volume: 20 μL or 2 μL
Flow rate: 0.35 mL/minute
Measurement temperature: 40° C.

### [Resin Composition]

The resin composition of one embodiment contains a curable prepolymer which contains a vinylbenzyl group and an indene ring and has a weight average molecular weight of 50,000 or higher. In the following description, this curable prepolymer which contains a vinylbenzyl group and an indene ring and has a weight average molecular weight of 50,000 or higher is sometimes referred to a simply “the curable prepolymer”.

The curable prepolymer is a prepolymer in which a portion of the vinylbenzyl groups having a polymerizable reactive group are retained in the prepolymer without contributing to the polymerization reaction. Because the curable prepolymer has this vinylbenzyl group, curing can be promoted by heating, pressurization, or a curing accelerator or the like, enabling a cured product to be obtained. In order to enable the curable prepolymer to be applied to a substrate or the like and molded, it is preferable that either the curable prepolymer itself is in liquid form, or the curable prepolymer is dissolved or dispersed in a solvent to form a liquid composition.

The weight average molecular weight (Mw) of the curable prepolymer is preferably 50,000 or higher, and more preferably 100,000 or higher, 150,000 or higher, or 300,000 or higher. Within these ranges, the surface tackiness of a coated product of the resin composition can be more appropriately suppressed. For example, the tack properties of a coated product such as a prepreg or resin film can be better improved. In the case of mixing with other components, the compatibility of the curable prepolymer with elastomers or the like can be better maintained. Further, when curing a coated product of the resin composition, separation of the resin can be better suppressed. For example, in a cured product such as a metal-clad laminate, layer separation of the resin can be better suppressed.

The weight average molecular weight (Mw) of the curable prepolymer, although not particular limited, may be, for example, 500,000 or less. From the viewpoints of the gelling suppression and coating properties of the resin composition, the weight average molecular weight (Mw) of the curable prepolymer may be 250,000 or less, 200,000 or less, or 150,000 or less. A value within these ranges also offers the advantage that during synthesis of the curable prepolymer, the solution viscosity of the synthesis system can be better maintained at an appropriate level.

For example, the weight average molecular weight (Mw) of the curable prepolymer may be 50,000 or higher but 500,000 or less, 100,000 or higher but 250,000 or less, or 150,000 or higher but 200,000 or less. On the other hand, from the viewpoints of the tackiness of the coated product and the moldability of the cured product, the weight average molecular weight (Mw) of the curable prepolymer is preferably 150,000 or higher but 500,000 or less, or 300,000 or higher but 500,000 or less. The weight average molecular weight (Mw) of the curable prepolymer may be measured in accordance with the method described above.

The curable prepolymer contains a vinylbenzyl group and an indene ring. Specific examples include a prepolymer containing a structural unit having a vinylbenzyl group and a structural unit having an indene ring, a prepolymer containing a vinylbenzyl group and an indene ring as substituents on the prepolymer skeleton, a prepolymer containing a structural unit having a vinylbenzyl group and having an indene ring as a substituent on the prepolymer skeleton, a prepolymer containing a structural unit having an indene ring and having a vinylbenzyl group as a substituent on the prepolymer skeleton, and a prepolymer containing a structural unit having a vinylbenzyl group and an indene ring.

The curable prepolymer is preferably a prepolymer containing a structural unit having a vinylbenzyl group and an indene ring, and is more preferably a prepolymer containing a structural unit having an indene ring and a vinylbenzyl group bonded directly to a carbon atom of the indene ring.

In the curable prepolymer, the indene ring may be unsubstituted or may have a substituent. For example, the indene ring may be represented by formula (1) shown below.

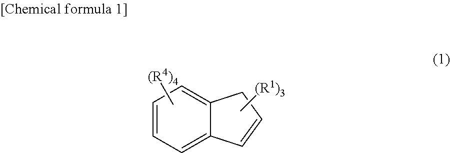

In formula (1), R¹ and R⁴ each independently represent a hydrogen atom, a halogen atom, a monovalent organic group, or a group having a bonding site with another structure. The monovalent organic group represented by R¹ and R⁴ may be an alkyl group of 1 to 5 carbon atoms, an alkoxy group of 1 to 5 carbon atoms, a thioalkoxy group of 1 to 5 carbon atoms, an aryl group of 6 to 20 carbon atoms, or an arylalkyl group of 7 to 20 carbon atoms. The halogen atom may be a fluorine atom, chlorine atom, bromine atom, or iodine atom. In formula (1), at least one of R¹ and R⁴ may represent a vinylbenzyl group. At least one of R¹ and R⁴ is a group having a bonding site with another structure. The plurality of R¹ groups and R⁴ groups may all be the same, or may be partially or completely different from each other. The benzene ring of the indene ring may be unsubstituted.

Furthermore, at least one of the R¹ and R⁴ groups that exist within the curable prepolymer may be an arylalkyl group other than a vinylbenzyl group, and that arylalkyl group may have no polymerizable unsaturated bond.

The indene ring may be represented by formula (1a) shown below.

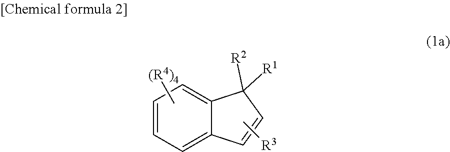

In formula (1a), R¹ and R⁴ may each independently represent the same groups or atoms as those exemplified above for formula (1), and R² and R³ may each independently represent the same groups or atoms as those exemplified for R¹ in formula (1). R¹ to R³ may all be the same, or may be partially or completely different from each other. The R⁴ groups may all be the same, or may be partially or completely different from each other. The benzene ring of the indene ring may be unsubstituted.

In the curable prepolymer, the vinylbenzyl group may be unsubstituted or may have a substituent. For example, the vinylbenzyl group may be represented by formula (2) shown below.

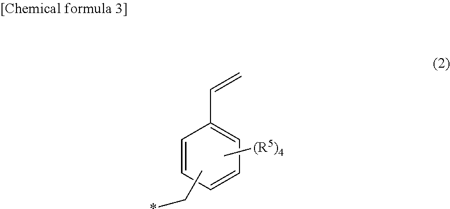

In formula (2), R⁵ represents a hydrogen atom, a halogen atom, or a monovalent organic group. The monovalent organic group represented by R⁵ may be an alkyl group of 1 to 5 carbon atoms, an alkoxy group of 1 to 5 carbon atoms, a thioalkoxy group of 1 to 5 carbon atoms, or an aryl group of 6 to 20 carbon atoms. The halogen atom may be a fluorine atom, chlorine atom, bromine atom, or iodine atom. The plurality of R⁵ groups may all be the same, or may be partially or completely different from each other. The vinylbenzyl group may be unsubstituted.

In the curable prepolymer, at least one R¹ group in formula (1) may represent a vinylbenzyl group. In the curable prepolymer, at least one R¹ group in formula (1) may represent a group containing a bonding site with another structure. In the curable prepolymer, at least one R¹ group in formula (1) may represent a vinylbenzyl group, with at least one of the remaining R¹ groups representing a group containing a bonding site with another structure.

Moreover, at least one of the R¹ groups that exist within the curable prepolymer may be an arylalkyl group other than a vinylbenzyl group, and that arylalkyl group may have no polymerizable unsaturated bond.

The curable prepolymer may contain a structure having a methylphenyl group, an indenyl group bonded to the methyl group of the methylphenyl group, and a vinylbenzyl group bonded to the indenyl group, or may contain a structure having a methylphenyl group, an indenyl group bonded at one of position 1, position 2 and position 3 to the methyl group of the methylphenyl group, and a vinylbenzyl group bonded to at least one of the remaining position 1, position 2 and position 3 of the indenyl group.

The curable prepolymer may contain a structure having a methylphenyl group, an indenyl group bonded to the methyl group of the methylphenyl group, and a vinylbenzyl group bonded to the indenyl group, as well as a structure having a methylphenyl group, an indenyl group bonded to the methyl group of the methylphenyl group, and an arylalkyl group other than a vinylbenzyl group bonded to the indenyl group, wherein the arylalkyl group may have no polymerizable unsaturated bond. Further, the curable prepolymer may contain a structure having a methylphenyl group, an indenyl group bonded at one of position 1, position 2 and position 3 to the methyl group of the methylphenyl group, and a vinylbenzyl group bonded to at least one of the remaining position 1, position 2 and position 3 of the indenyl group, as well as a structure having a methylphenyl group, an indenyl group bonded at one of position 1, position 2 and position 3 to the methyl group of the methylphenyl group, and an arylalkyl group other than a vinylbenzyl group bonded to at least one of the remaining position 1, position 2 and position 3 of the indenyl group, wherein the arylalkyl group may have no polymerizable unsaturated bond.

In an indenyl group and an indene ring, position 1, position 2 and position 3 are as shown below.

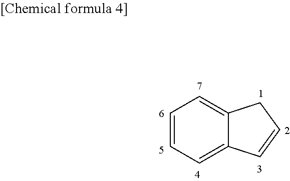

For example, the curable prepolymer may contain a structural unit represented by formula (3) shown below.

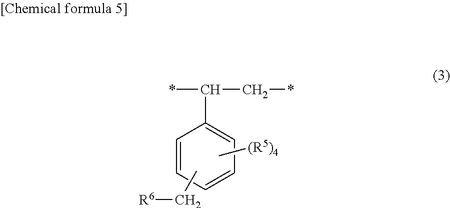

In formula (3), R⁶ represents an unsubstituted or substituted indenyl group. R⁵ may be the same as described above in formula (2). Some or all of the R⁵ groups may be hydrogen atoms. For example, the curable prepolymer may contain a structural unit represented by formula (4) shown below.

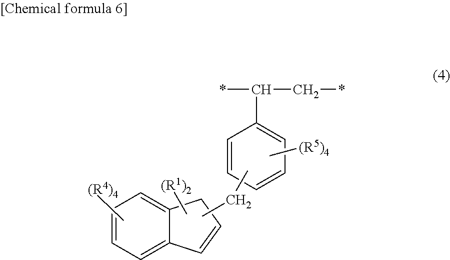

In formula (4), R¹ and R⁴ may be each independently the same as described above in formula (1), and R⁵ may be the same as described above in formula (2). At least one R¹ group may be an unsubstituted or substituted vinylbenzyl group. At least one R¹ group may be a group having a bonding site with another structure. Some or all of the R⁴ and R⁵ groups may be hydrogen atoms.

Moreover, at least one of the R¹ groups that exists within the curable prepolymer may represent an arylalkyl group other than a vinylbenzyl group, and that arylalkyl group may have no polymerizable unsaturated bond.

The curable prepolymer may be a polymer of one or more monomers. Examples of these monomers include monomers having one, or two or more vinylbenzyl groups, monomers having one, or two or more indene rings, and monomers having one, or two or more vinylbenzyl groups and indene rings. The polymerization should not proceed to completion, and should be halted in a state where some portion of the vinylbenzyl groups derived from the monomer(s) is still retained. For example, in order to obtain the curable prepolymer in a liquid state, the polymerization may be stopped when the viscosity of the polymerization reaction system for the curable prepolymer reaches a certain state. An oligomer may be used in combination with, or instead of, the monomer.

The curable prepolymer may be, for example, a polymer containing a structural unit derived from a vinylbenzyl compound having a vinylbenzyl group and an indene ring within the same molecule. This vinylbenzyl compound may be a monomer, an oligomer, or a combination thereof, but from a molecular design perspective, a monomer is preferred. In the following description, a vinylbenzyl compound having a vinylbenzyl group and an indene ring is sometimes referred to as simply a vinylbenzyl compound. The curable prepolymer may have only structural units derived from a single vinylbenzyl compound, or may have structural units derived from a plurality of types of vinylbenzyl compound.

The vinylbenzyl compound may be a compound having one, or two or more vinylbenzyl groups, and one, or two or more indene rings per molecule, may be a compound having one, or two or more vinylbenzyl groups, and one indene ring per molecule, or may be a compound having one to three vinylbenzyl groups, and one indene ring per molecule. The vinylbenzyl compound may be a compound in which a vinylbenzyl group is bonded directly to a carbon atom of the indene ring.

The vinylbenzyl compound may be a compound having one, or two or more vinylbenzyl groups, one, or two or more indene rings, and one, or two or more arylalkyl groups other than a vinylbenzyl group per molecule. The vinylbenzyl compound may be a compound having one, or two or more vinylbenzyl groups, one indene ring, and one, or two or more arylalkyl groups other than a vinylbenzyl group per molecule. The vinylbenzyl compound may be a compound in which a vinylbenzyl group and an arylalkyl group other than a vinylbenzyl group are each bonded directly to a carbon atom of the indene ring. The arylalkyl group other than a vinylbenzyl group may have no polymerizable unsaturated bond.

The curable prepolymer may be a polymer containing a structural unit derived from a compound having an indene ring, and having one to three vinylbenzyl groups bonded to any of position 1, position 2 and position 3 of the indene ring, or may be a polymer containing a structural unit derived from a compound having two or three vinylbenzyl groups bonded to any of position 1, position 2 and position 3 of the indene ring.

Furthermore, the curable prepolymer may be a polymer containing a structural unit derived from a compound having an indene ring, having one or two vinylbenzyl groups bonded to any of position 1, position 2 and position 3 of the indene ring, and having one or two arylalkyl groups other than a vinylbenzyl group bonded to any of position 1, position 2 and position 3 of the indene ring. Furthermore, the curable prepolymer may be a polymer containing both a structural unit derived from a compound having an indene ring, having one to three vinylbenzyl groups bonded to any of position 1, position 2 and position 3 of the indene ring, and having no arylalkyl groups other than a vinylbenzyl group, and a structural unit derived from a compound having an indene ring, having one or two vinylbenzyl groups bonded to any of position 1, position 2 and position 3 of the indene ring, and having one or two arylalkyl groups other than a vinylbenzyl group bonded to any of position 1, position 2 and position 3 of the indene ring.

In a polymerization using these types of monomers, by obtaining the curable prepolymer in a state where the polymerization has not proceeded to completion, a portion of the vinylbenzyl groups from the monomer will contribute to the polymerization and form the prepolymer skeleton in the curable prepolymer, whereas another portion of the vinylbenzyl groups from the monomer will not participate in the polymerization, but rather exist as vinylbenzyl groups within the prepolymer.

In the vinylbenzyl compound, each of the indene ring and the vinylbenzyl group may be unsubstituted or may have a substituent. The substituent for the indene ring may be one of the groups mentioned above for R¹ and R⁴ in formula (1) and formula (2). The substituent for the vinylbenzyl group may be one of the groups mentioned above for R⁵ in formula (3).

The vinylbenzyl compound may be a compound represented by formula (5-1) or (5-2) shown below.

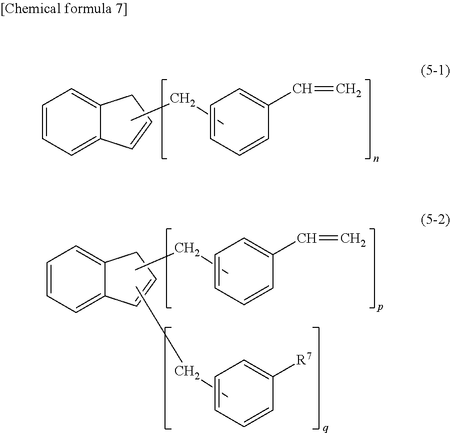

In formula (5-1), n represents an integer of 1 to 3. Further, n is preferably either 2 or 3, and more preferably 2. The resin composition containing the curable prepolymer may include curable prepolymers that are copolymers produced from a plurality of monomers having different n values. In such cases, the average value for n is preferably within a range from 1 to 3, more preferably from 2 to 3, and even more preferably from 2.0 to 2.5. In formula (5-1), the indene ring and the vinylbenzyl group may each have a substituent.

In formula (5-1), the vinylbenzyl group may be bonded directly to the carbon atom at any of position 1, position 2 and position 3 of the indene ring, but is preferably bonded to position 1, or to a combination of position 1 and position 3. Either one or two vinylbenzyl groups may be bonded at each position. For example, vinylbenzyl groups may be bonded at a combination of position 1, position 1′ and position 3 of the indene ring, or at a combination of position 1 and position 1′ of the indene ring.

In formula (5-1), the methyl group of the vinylbenzyl group may be located at any one of the o-, m-and p-positions, but is preferably located at the m-or p-position. In those cases where the polymer is obtained using two or more monomers, a mixture of the o-isomer, m-isomer and p-isomer is possible. In such cases, a combination of the m-isomer and the p-isomer is preferred, and the mass ratio between the m-isomer and the p-isomer is preferably within a range from 40:60 to 60:40.

In formula (5-2), R⁷ represents a hydrogen atom or a saturated hydrocarbon group of 1 to 6 carbon atoms. R⁷ may be an alkyl group of 1 to 3 carbon atoms. In the following description, a structural unit shown below included within formula (5-2) is sometimes referred to as an “arylalkyl group”.

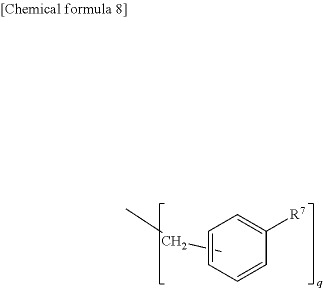

In formula (5-2), p represents by an integer of 1 to 3, and q represents 0, 1 or 2, provided that p+q is an integer of 1 to 3. The resin composition containing the curable prepolymer may contain a curable prepolymer that is a copolymer of a plurality of monomers having different values for p and q. In such cases, the average value for p is preferably within a range from 1 to 3, more preferably from 2 to 3, and even more preferably from 2.0 to 2.5. Further, the average value for q is preferably within a range from 0.3 to 1, and more preferably from 0.5 to 0.8. In formula (5-2), the indene ring, the vinylbenzyl group and the arylalkyl group may each have a substituent.

In formula (5-2), the vinylbenzyl group and the arylalkyl group may be bonded directly to the carbon atom at any of position 1, position 2 and position 3 of the indene ring.

In formula (5-2), the methyl group of the vinylbenzyl group may be located at any one of the o-, m-and p-positions, but is preferably located at the m-or p-position. In those cases where the polymer is obtained using two or more monomers, a mixture of the o-isomer, m-isomer and p-isomer is possible. In such cases, a combination of the m-isomer and the p-isomer is preferred, and the mass ratio between the m-isomer and the p-isomer is preferably within a range from 40:60 to 60:40.

The curable prepolymer described above may be a homopolymer or a copolymer. The homopolymer may be a homopolymer containing a unit having a vinylbenzyl group and an indene ring. Examples of the copolymer include copolymers containing two or more units each having a vinylbenzyl group and an indene ring, copolymers containing one or more of each of a unit having a vinyl group and a unit having an indene ring, and copolymers of these copolymers and another unit. In terms of achieving a lower dielectric constant and a lower dielectric loss tangent, the curable prepolymer need not contain any other units besides units having a vinylbenzyl group and an indene ring, units having a vinylbenzyl group, and units having an indene ring. From this viewpoint, in the curable prepolymer, the total mass of units having a vinylbenzyl group and an indene ring, units having a vinylbenzyl group, and units having an indene ring, relative to the total mass of the curable prepolymer, is preferably at least 50% by mass, and more preferably at least 60% by mass, at least 80% by mass, or 90% by mass or greater. Among the various possibilities, in the curable prepolymer, the total mass of units having a vinylbenzyl group and an indene ring, relative to the total mass of the curable prepolymer, is preferably at least 50% by mass, and more preferably at least 60% by mass, at least 80% by mass, or 90% by mass or greater.

The curable prepolymer described above may have substituents, but because the curable prepolymer is preferably a hydrocarbon compound, the curable prepolymer preferably does not have polar groups. Examples of polar groups include ester linkages (—CO—O—) and ether linkages (—C—O—) and the like. Moreover, from the viewpoint of the dielectric characteristics, the curable prepolymer preferably does not contain hetero atoms. Examples of hetero atoms include oxygen atoms, nitrogen atoms and sulfur atoms. In particular, the curable prepolymer preferably does not contain oxygen atoms.

A method for synthesizing the curable prepolymer is described below. The curable prepolymer can be obtained, for example, by polymerizing a compound containing a vinylbenzyl group and an indene ring. In another example, the curable prepolymer can also be obtained by copolymerizing a compound having a vinylbenzyl group and a compound having an indene ring. In yet another example, the curable prepolymer can be obtained by introducing a vinylbenzyl group and an indene ring into a polymer skeleton. A method for polymerizing a compound containing a vinylbenzyl group and an indene ring is described below. However, the curable prepolymer is not limited to prepolymers synthesized using this synthesis method.

First is a description of an example of a method for synthesizing the vinylbenzyl compound. Among the various possible vinylbenzyl compounds, a method for synthesizing a vinylbenzyl compound represented by the above formula (5-1) may involve, for example, reacting indene and a styrene having a halogenated methyl group in the presence of a basic compound. Examples of the styrene having a halogenated methyl group include o-chloromethylstyrene, m-chloromethylstyrene and p-chloromethylstyrene, and any one of these compounds or a mixture of two or more compounds may be used. The amount of the styrene having a halogenated methyl group per 1 mol of indene may be, for example, within a range from 1 to 3 mol, may be within a range from 2 to 3 mol, or may be within a range from 2.0 to 2.5 mol. Examples of the basic compound include alkali metal hydroxides and alkali metal alkoxides.

Further, among the various possible vinylbenzyl compounds, a method for synthesizing a vinylbenzyl compound represented by the above formula (5-2) may involve, for example, reacting indene, a styrene having a halogenated methyl group, and an aryl compound having a halogenated methyl group (but excluding styrenes having a halogenated methyl group) in the presence of a basic compound. Examples of the styrene having a halogenated methyl group include the same compounds as those mentioned above, and any one of these compounds or a mixture of two or more compounds may be used. Examples of the aryl compound having a halogenated methyl group include α-chlorotoluene and α-chloro-p-xylene. The amount of the styrene having a halogenated methyl group per 1 mol of indene may be, for example, within a range from 1 to 3 mol, may be within a range from 2 to 3 mol, or may be within a range from 2.0 to 2.5 mol. The amount of the aryl compound having a halogenated methyl group per 1 mol of indene may be, for example, within a range from 0.3 to 1 mol, or may be within a range from 0.5 to 0.8 mol. The total number of moles of the styrene having a halogenated methyl group and the aryl compound having a halogenated methyl group per 1 mol of indene may be within a range from 1.5 to 3 mol, may be within a range from 2 to 3 mol, or may be within a range from 2.5 to 2.9 mol. Examples of the basic compound include the same compounds as those mentioned above.

The above reaction may also use a phase transfer catalyst. Examples of this phase transfer catalyst include tetra-n-butylammonium bromide and the like. The reaction may be conducted as a solution polymerization. The reaction may, for example, be conducted under heating and stirring. A polymerization inhibitor may be added to the reaction system. If necessary, the obtained reaction product may be purified using conventional methods such as concentration, re-precipitation, or washing or the like.

In the method for synthesizing the curable prepolymer, a single vinylbenzyl compound may be used alone, or a combination of two or more such compounds may be used. For example, in a method for synthesizing a vinylbenzyl compound represented by formula (5-1) or (5-2), a compound is synthesized in which a vinylbenzyl group is bonded directly to the carbon atom of at least one of position 1, position 2 and position 3 of the indene ring, but the compound may be produced as a mixture of vinylbenzyl compounds of two or more isomers having different bonding locations.

Next is a description of a method for polymerizing the vinylbenzyl compound to obtain the curable prepolymer. The polymerization of the vinylbenzyl compound is preferably conducted by radical polymerization to ensure there is no production of polar components in the reaction product. Radical polymerization can be conducted by using a radical polymerization initiator. The polymerization may be conducted by solution polymerization, and there are no particular limitations on the polymerization solvent. For example, one solvent or a combination of two or more solvents selected from among the organic solvents described below for use in the resin composition may be used as the polymerization solvent.

The radical polymerization initiator may be a thermal radical polymerization initiator or a photo radical polymerization initiator, but a thermal radical polymerization initiator is preferred. There are no particular limitations on the radical polymerization initiator, and examples include azo-based polymerization initiators and organic peroxide-based polymerization initiators.

Examples of the azo-based polymerization initiators include 2,2′-azobis(isobutyronitrile), 2,2′-azobis(2-methylpropanenitrile), 2,2′-azobis(2-methylbutyronitrile), 2,2′-azobis(4-methoxy-2,4-dimethylvaleronitrile), dimethyl 2,2′-azobis(2-methylpropionate), 1,1′-azobis(cyclohexanecarboxylic acid) dimethyl ester, 2,2′-azobis [N-(2-propenyl)-2-methylpropionamide], 2,2′-azobis(N-butyl-2-methylpropionamide), 4,4′-azobis(3,3,4,4,5,5,6,6,7,7,8,8,8-tridecafluorooctyl-4-cyanopentanoate), and 1,1′-azobis(cyclohexane-1-carbonitrile).

Examples of the organic peroxide-based polymerization initiators include dicumyl peroxide, dibenzoyl peroxide, 2-butanone peroxide, tert-butyl perbenzoate, di-tert-butyl peroxide, 2,5-dimethyl-2,5-di(t-butylperoxy) hexane, bis(tert-butylperoxyisopropyl)benzene, and tert-butyl hydroperoxide.

In order to prevent the incorporation of polar components into the resin composition, the generation of by-products that exhibit polarity in the polymerization system is preferably reduced. From this viewpoint, among the various possible radical polymerization initiators, the use of compounds having a minimal amount of oxygen atoms is preferred. Azo-based polymerization initiators are particularly preferred as these types of compounds. Amongst such compounds, azo-based polymerization initiators containing no hetero atoms other than the two nitrogen atoms (N) of the azo group are preferred. Examples include compounds represented by formula (6) shown below.

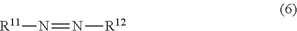

In formula (6), R¹¹ and R¹² each independently represent a hydrogen atom or a monovalent functional group, provided that at least one of R¹¹ and R¹² represents a monovalent functional group. R¹¹ and R¹² may be the same or different. The monovalent functional group is preferably a hydrocarbon group, may be a saturated hydrocarbon group or an unsaturated hydrocarbon group, and may be an aliphatic hydrocarbon group or an aromatic hydrocarbon group. The monovalent functional group is preferably a saturated or unsaturated aliphatic hydrocarbon group, and is more preferably an alkyl group.

The alkyl group may be a chain-like alkyl group or a cyclic alkyl group. The chain-like alkyl group may be either a linear alkyl group or a branched alkyl group. The cyclic alkyl group may have a substituent bonded to a carbon atom within the ring.

The alkyl group may be an alkyl group of 1 to 10 carbon atoms, 3 to 8 carbon atoms, or 4 to 8 carbon atoms. Examples of the alkyl group include a methyl group, ethyl group, n-propyl group, isopropyl group, n-butyl group, isobutyl group, sec-butyl group, tert-butyl group, n-pentyl group, isopentyl group, neopentyl group, n-hexyl group, isohexyl group, cyclohexyl group, methylcyclohexyl group, cyclohexylmethyl group, heptyl group, octyl group, isooctyl group, 2-ethylhexyl group, nonyl group, decyl group, 1,1′,3,3′-tetramethylbutyl group, and 2,2′,4,4′-tetramethylbutyl group.

Specific examples of the compound represented by formula (6) include 2,2′-azobis(2,4,4-trimethylpentane) and 2,2′-azobis(2,4-dimethylvaleronitrile).

The amount used of the radical polymerization initiator may be adjusted appropriately in accordance with the desired degree of polymerization for the curable prepolymer. Further, the amount used of the radical polymerization initiator may also be adjusted in accordance with factors such as the number of functional vinylbenzyl groups within the vinylbenzyl compound. For example, the amount used of the radical polymerization initiator may be within a range from 0.01 to 5 parts by mass, from 0.1 to 4 parts by mass, or from 0.5 to 2 parts by mass per 100 parts by mass of the vinylbenzyl compound within the polymerization system.

In the reaction for polymerizing the vinylbenzyl compound to obtain the curable prepolymer, from the viewpoint of controlling the degree of polymerization of the curable prepolymer to ensure that the amount of unreacted vinylbenzyl groups retained within the curable prepolymer is an effective amount, a polymerization inhibitor or a chain transfer agent or the like may be used. Further, the weight average molecular weight of the polymerization system may be measured periodically, and the polymerization halted when a curable prepolymer of the desired degree of polymerization has been obtained,

Next is a description of optional components that may be included in the resin composition. The resin composition may contain an elastomer as an optional component. Examples of the elastomer include diene-based elastomers, olefin-based elastomers, polysulfide-based elastomers, silicone-based elastomers, fluorine-based elastomers, urethane-based elastomers, and ether-based elastomers. More specific examples include diene-based elastomers such as styrene-butadiene rubber (SBR), butadiene rubber (BR), styrene-isoprene rubber, isoprene rubber (IR), chloroprene rubber (CR), and acrylonitrile-butadiene rubber (NBR). Specific examples of the olefin-based elastomers include butyl rubber (IIR), ethylene-propylene rubber, ethylene-vinyl acetate rubber, chlorosulfonated polyethylene, and acrylic rubber. These elastomers may be either unhydrogenated or hydrogenated. Among the various possibilities, from the viewpoints of achieving a low dielectric constant as well as favorable heat resistance, styrene-butadiene rubber (SBR) is preferred.

Because styrene-butadiene rubber contains no oxygen atoms within the molecule, the number of polar groups in a cured product obtained using a resin composition containing a styrene-butadiene rubber can be reduced, and the dielectric constant and dielectric loss tangent can be further lowered. Further, styrene-butadiene rubber has benzene rings derived from styrene within the molecule, and therefore the compatibility with the curable prepolymer having vinylbenzyl groups in the resin composition is favorable, and the moldability of the obtained cured products can be improved.

Examples of the styrene-butadiene rubber include styrene-butadiene copolymers and styrene-butadiene-styrene copolymers. These copolymers may be unhydrogenated or hydrogenated. In the case of a hydrogenated rubber, some or all of the carbon-carbon double bonds of the butadiene may be converted to saturated bonds. Examples of these hydrogenated rubbers include styrene-ethylene-butylene-styrene copolymers, and styrene-ethylene-butylene copolymers and the like.

In the styrene-butadiene rubber or hydrogenated product thereof, from the viewpoint of the dielectric constant, the amount of structural units derived from styrene is preferably within a range from 5 to 80% by mass, more preferably from 10 to 75% by mass, even more preferably from 15 to 60% by mass, and still more preferably from 20 to 45% by mass. Further, within these ranges, the viscoelasticity of the styrene-butadiene rubber or hydrogenated product thereof is also favorable, and the adhesion of the resin composition to the coating target material can be further improved.

From the viewpoints of solvent solubility, moldability, and flexibility and the like, the weight average molecular weight (Mw) of the elastomer is preferably within a range from 50,000 to 500,000, more preferably from 70,000 to 300,000, and even more preferably from 100,000 to 200,000. From the viewpoints of solvent solubility, moldability, and flexibility and the like, the number average molecular weight (Mn) of the elastomer is preferably within a range from 10,000 to 200,000, more preferably from 30,000 to 150,000, and even more preferably from 50,000 to 120,000. From the viewpoint of the compatibility with the curable prepolymer, the value of Mw/Mn for the elastomer is preferably within a range from 1.0 to 5.0, more preferably from 1.5 to 3.5, and even more preferably from 2.0 to 3.0. The method used for measuring the weight average molecular weight (Mw) and number average molecular weight (Mn) of the elastomer may conform with the method described above.

A single elastomer may be used alone, or a combination of two or more elastomers may be used. The amount of elastomer used per 100 parts by mass of the curable prepolymer may be within a range from 1 to 80 parts by mass, from 10 to 70 parts by mass, from 20 to 60 parts by mass, or from 30 to 40 parts by mass.

In the resin composition, because the curable prepolymer itself exhibit excellent tack properties for the coated products and yields excellent moldability for the cured products, the amount of elastomer added can be reduced, and an elastomer need not be added to the resin composition. On the other hand, in the resin composition, because the curable prepolymer has no polar groups, the compatibility with an elastomer in the resin composition tends to be favorable, meaning the amount of the elastomer can also be increased. Moreover, in those cases where the weight average molecular weight (Mw) of the curable prepolymer is 50,000 or higher, the compatibility with the elastomer is even better, meaning the amount of the elastomer can be increased even further.

The resin composition may contain a filler as an optional component. Examples of the filler include inorganic fillers and organic fillers, but from the viewpoint of the dielectric characteristics, an inorganic filler is preferred. Specific examples of inorganic fillers include silica (SiO₂), alumina (Al₂O₃), titanium oxide, barium titanate, strontium titanate, potassium titanate, calcium titanate, aluminum carbonate, magnesium hydroxide, aluminum hydroxide, aluminum silicate, calcium carbonate, calcium silicate, magnesium silicate, silicon nitride, boron nitride, aluminum borate, silicon carbide, mica, beryllia, clay, and talc.

There are no particular limitations on the shape and size of the inorganic filler. For example, the average particle size of the inorganic filler may be within a range from 0.01 to 20 μm, from 0.1 to 10 μm, or from 1 to 5 μm. In this description, the average particle size of an inorganic filler represents the particle size corresponding with a cumulative value of 50% in a volume-based particle size distribution produced using a laser diffraction/scattering method.

A single filler may be used alone, or a combination of two or more fillers may be used. The amount of filler used per 100 parts by mass of the curable prepolymer may be within a range from 10 to 500 parts by mass, from 50 to 400 parts by mass, from 100 to 350 parts by mass, or from 200 to 300 parts by mass. In those cases where the resin composition also contains an elastomer, the amount of inorganic filler used per 100 parts by mass of the combined mass of the curable prepolymer and the elastomer may be within a range from 50 to 400 parts by mass, from 100 to 350 parts by mass, or from 200 to 300 parts by mass.

If the curable prepolymer is in liquid form, then the resin composition may contain the curable prepolymer while being solvent-free. Alternatively, the resin composition may contain the curable prepolymer and a solvent. The solvent can be used to adjust the viscosity of the resin composition and further improve the coating properties. An organic solvent is preferred as the solvent.

Examples of the organic solvent include alcohol-based solvents such as ethanol, propanol, butanol, methyl cellosolve, ethylene glycol monobutyl ether, and propylene glycol monomethyl ether; ketone-based solvents such as acetone, methyl ethyl ketone, methyl isobutyl ketone, and cyclohexanone; ether-based solvents such as tetrahydrofuran; aromatic hydrocarbon-based solvents such as toluene, xylene, and mesitylene; nitrogen atom-containing solvents such as dimethylformamide, dimethylacetamide, and N-methylpyrrolidone; sulfur atom-containing solvents such as dimethyl sulfoxide; and ester-based solvents such as γ-butyrolactone. A single organic solvent may be used alone, or a combination of two or more organic solvents may be used.

In those cases where the resin composition contains a solvent, the mass of the solid component, which includes all the components other than the solvent, relative to the total mass of the resin composition, may be within a range from 10 to 80% by mass, from 30 to 70% by mass, or from 40 to 60% by mass.

The resin composition may also contain other additives besides the components described above, provided the effects of the present invention are not impaired. Examples of these other additives include curing agents, curing accelerators, flame retardants, antioxidants, thermal stabilizers, antistatic agents, ultraviolet absorbers, pigments, colorants, and lubricants. Further, the resin composition may also contain additional thermosetting resins and thermoplastic resins besides those described above. The resin composition may also contain some radical polymerization initiator or by-products thereof resulting from the prepolymer polymerization. Furthermore, the resin composition may also contain additional radical polymerization initiator as a curing accelerator.

There are no particular limitations on the method used for producing the resin composition. The resin composition according to one embodiment of the invention is not limited by the production method employed, provided the characteristics are as described in the present description. In one example of the production method, the resin composition can be obtained simply as the curable prepolymer, or by mixing the curable prepolymer with other optional components. For example, the resin composition can be obtained by dissolving or dispersing the curable prepolymer in a solvent, and then adding and mixing an elastomer, a filler, and any other additives and the like as required. There are no particular limitations on conditions such as the order in which components are added and mixed, the temperature, and the mixing time and the like, and these conditions may be set appropriately in accordance with the types of raw materials, the production scale, and the production apparatus and the like.

### [Cured Product]

One embodiment of the invention provides a cured product of the resin composition. Details regarding the resin composition are as described above. Further, because this cured product is provided using a resin composition containing the curable prepolymer, the tack properties of the coated product of the resin composition can be improved, and the occurrence of molding marks on the cured product can be reduced. Furthermore, in those cases where the cured product is provided using a resin composition containing the curable prepolymer and an elastomer, by ensuring the weight average molecular weight (Mw) of the curable prepolymer is 50,000 or higher, the compatibility within the resin composition can be improved, and the occurrence of layer separation caused by maldistribution of the components within the obtained cured product can be reduced.

The cured product of the resin composition has a dielectric constant (Dk) at 25° C. and 10 GHz that is preferably not more than 4.0, more preferably not more than 3.5, and even more preferably 3.2 or lower. More specifically, the cured product of the resin composition may have a dielectric constant (Dk) at 25° C. and 10 GHz that is 3.20 or lower, 3.15 or lower, or 3.10 or lower. The lower the value of the dielectric constant (Dk) at 25° C. and 10 GHz for the cured product of the resin composition, the better, and although there is no particular limitation on the lower limit for this value, considering the balance with other physical properties, the dielectric constant may be, for example, at least 2.3, or 2.4 or higher.

The cured product of the resin composition has a dielectric loss tangent (Df) at 25° C. and 10 GHz that is preferably not more than 0.0080, more preferably not more than 0.0012, and even more preferably 0.0011 or lower. The lower the value of the dielectric loss tangent (Df) at 25° C. and 10 GHz for the cured product of the resin composition, the better, and although there is no particular limitation on the lower limit for this value, considering the balance with other physical properties, the dielectric loss tangent may be, for example, 0.0001 or higher.

Moreover, in those cases where the resin composition does not contain a filler, the cured product of the resin composition has a dielectric constant (Dk) at 25° C. and 10 GHz that is preferably not more than 3.0, more preferably not more than 2.7, and even more preferably 2.5 or lower. More specifically, the cured product of the resin composition may have a dielectric constant (Dk) at 25° C. and 10 GHz that is 2.70 or lower, 2.65 or lower, or 2.60 or lower. Furthermore, in those cases where the resin composition does not contain a filler, the cured product of the resin composition has a dielectric loss tangent (Df) at 25° C. and 10 GHz that is preferably not more than 0.0020, more preferably not more than 0.0014, even more preferably 0.0012 or lower, and still more preferably 0.0010 or lower.

In this description, the values for the dielectric constant (Dk) and the dielectric loss tangent (Df) at 25° C. and 10 GHz are measured in the 10 GHz band at 25° C. in accordance with the SPDR method (Split Post Dielectric Resonator). For example, a “PNA Network Analyzer N5227A” (product name) manufactured by Agilent Technologies, Inc. may be used as the measurement apparatus. The sample of the cured product of the resin composition used for the measurements of the dielectric constant (Dk) and the dielectric loss tangent (Df) is prepared by obtaining a cured product using the resin composition, and molding the cured product into a sample of 5 cm×10 cm with a thickness of 1 cm.

The samples that represent the measurement targets for the dielectric constant (Dk) and the dielectric loss tangent (Df) of cured products of resin compositions were prepared by curing the resin composition to achieve a C-stage state as described in JIS K 6800 (1985).

### [Prepreg]

One embodiment of the invention provides a prepreg containing either a resin composition or a semi-cured product of the resin composition. Details regarding the resin composition are as described above.

The prepreg may contain the resin composition or a semi-cured product of the resin composition, and a fibrous substrate. In the prepreg, the curable prepolymer may exist in an uncured state, or the curable prepolymer may exist in a partially or completely semi-cured state.

The prepreg can be obtained, for example, by applying the resin composition to a fibrous substrate and then drying the resulting coated product. In a different method, the prepreg can be obtained by impregnating the fibrous substrate with the resin composition, and then drying the fibrous substrate that has been impregnated with the curable prepolymer. The drying process is preferably conducted at a temperature at least as high as the temperature at which volatile components such as solvents contained in the resin composition can be removed, and depending on the application, may be within a temperature range that results in semi-curing of the curable prepolymer within the resin composition. Further, the drying process may be adjusted so that the curable prepolymer contained in the resin composition does not undergo complete curing. From this type of viewpoint, the drying temperature may be within a range from 80 to 200° C., and the drying time may be adjusted within a range from 1 to 30 minutes in accordance with factors such as the drying temperature, the drying device, and the scale of the drying device.

In this description, the expression “semi-cured product of the curable prepolymer” means a state in which a portion of the vinylbenzyl groups contained in the curable prepolymer have contributed to the curing reaction, while the remaining vinylbenzyl groups are retained within the product. A semi-cured product of the curable prepolymer having a vinylbenzyl group is a state in which the curing reaction can be continued by an additional heat treatment or the like. In this description, one indicator of a semi-cured product is the B-stage state described in JIS K 6800 (1985).

The fibrous substrate may be a woven substrate, a knitted substrate, or a non-woven substrate. The fibrous substrate may be provided in a form such as a chopped-strand mat or a roving or the like. The fiber material may be either inorganic fiber or organic fiber. Examples of inorganic fiber include glass fiber and carbon fiber. Specific examples of glass fiber include E-glass, NE-glass, D-glass, S-glass and Q-glass. Examples of organic fiber include polyimide, polyester, and tetrafluoroethylene. The fibrous substrate may contain only one of these types of fiber, or may be a mixed fiber containing two or more types of fiber. From the viewpoints of the dielectric characteristics and heat resistance, the fibrous substrate is preferably an inorganic fiber, and more preferably a glass fiber.

The fibrous substrate may be selected appropriately in accordance with the intended application for the prepreg, but a sheet-like fibrous substrate is preferred. The sheet-like fibrous substrate may be, for example, any of the various sheet-like fibrous substrates used in conventional laminates for electrical insulation materials. Although there are no particular limitations on the thickness of the sheet-like fibrous substrate, for example, a thickness of 0.02 to 0.5 mm is preferred. Here, the thickness is determined by measuring the thickness at 5 equally spaced points across the entire surface of the sheet-like fibrous substrate, and then calculating the arithmetic mean of the 5 measurements.

In the prepreg, the total mass of the curable prepolymer and any elastomer, relative to the combined mass of the curable prepolymer, the elastomer and the fibrous substrate, may be within a range from 20 to 90% by mass, or from 30 to 80% by mass. However, the mass of the elastomer may be 0% by mass. Within these ranges, impregnation of the resin into the fibrous substrate of the prepreg can be achieved more easily. Further, the step of assembling the prepreg into a molded item and then conducting curing can be performed more easily.

### [Resin Film]

One embodiment of the invention provides a resin film containing the resin composition or a semi-cured product of the resin composition. Details regarding the resin composition are as described above.

A resin film means a state in which the resin composition has been molded into film form. In the resin film, the curable prepolymer may exist in an uncured state, or the curable prepolymer may be partially or completely in a semi-cured state. A cured product can then be obtained by curing this resin film by conducting a heat treatment or the like.

The resin film can be obtained, for example, by applying the resin composition to a coating target material and then drying the resulting coated product. The drying process may be conducted in the same manner as that described above in the method for producing a prepreg. Following drying of the resin film on the coating target material, the product may be provided a combination of the resin film and the coating target material. For example, in this method, the resin film may be provided as an insulating layer or the like on a printed wiring board. In a different method, following drying of the resin film on the coating target material, the resin film may be detached from the coating target material and provided as a resin film product.

The coating target material may be either an inorganic substrate or an organic substrate, and examples include glass substrates, metal substrates such as metal foils and metal sheets, plastic substrates such as plastic sheets and plastic films, and paper substrates. The type of fibrous substrate described above in relation to the prepreg may also be used. In order to enable the resin film to be detached from the coating target material, a coating target material having a release layer formed on the surface may also be used.

Although there are no particular limitations on the dielectric constants (Dk) and dielectric loss tangents (Df) of the prepreg and the resin film, these values preferably independently fall within the above numerical ranges for the dielectric constant (Dk) and dielectric loss tangent (Df) of the resin composition.

### [Metal-Clad Laminate]

One embodiment of the invention provides a metal-clad laminate having a cured product of the resin composition and a metal foil. Details regarding the resin composition are as described above.

The metal-clad laminate preferably has a resin cured product layer containing the resin cured product, and a metal foil formed on at least one surface of the resin cured product layer. The resin cured product layer is a layer containing a cured product of the resin composition, and may be a cured product of the prepreg or resin film described above. Examples of more useful applications include laminates in which a metal foil is formed on at least one surface of the cured product of a prepreg, and a laminate in which a metal foil is formed on both surfaces of the cured product of the prepreg is particularly preferred. The resin cured product layer may be a single sheet-like prepreg, with the metal foil formed on at least one surface thereof, or may be a cured product prepared by laminating two or more sheet-like prepregs, with the metal foil then formed on at least one of the outermost surfaces of the laminated prepregs. In a particularly useful application, the metal-clad laminate is obtained by laminating two or more sheet-like prepregs, and then forming metal foils on both surfaces of the resulting laminate.

The metal-clad laminate can be produced, for example, by arranging a metal foil on one surface or both surfaces of a sheet-like prepreg, and subsequently conducting heated compression molding. This causes the curing reaction of the sheet-like prepreg to proceed, yielding a cured product of the prepreg. In the heated compression molding, a single prepreg may be used alone, or two or more prepregs may be laminated together. There are no particular limitations on the heated compression conditions, and the process may be conducted, for example, at a temperature of 100 to 300° C. for a period of 10 to 300 minutes at a pressure of 1.5 to 5 MPa. Further, following the heated compression, additional heating may be conducted to enable the curing of the prepreg to proceed further. In such cases, the temperature for this additional heating may be within a range from 100 to 300° C. Examples of the heated compression method include methods using an autoclave molding machine, a multistage press, a multistage vacuum press, or a continuous molding machine or the like.

There are no particular limitations on the metal of the metal foil, and examples include copper, nickel, aluminum, gold, silver, platinum, molybdenum, ruthenium, tungsten, iron, titanium and chromium, as well as alloys and the like containing two or more of these metal elements. From an industrial perspective, the metal may be simple metals of copper, nickel or aluminum. By using copper as the copper foil, a copper-clad laminate can be provided.

The dielectric characteristics of the resin cured product in a state where the metal foil of the metal-clad laminate has been removed (hereinafter also referred to as simply the dielectric constant of the metal-clad laminate or the dielectric loss tangent of the metal-clad laminate) are preferably as described below.

The dielectric constant (Dk) of the metal-clad laminate at 25° C. and 10 GHz is preferably not more than 4.0, more preferably not more than 3.5, and even more preferably 3.2 or lower. More specifically, the dielectric constant (Dk) of the metal-clad laminate at 25° C. and 10 GHz may be 3.20 or lower, 3.15 or lower, or 3.10 or lower. The lower the value of the dielectric constant (Dk) at 25° C. and 10 GHz for the metal-clad laminate, the better, and although there is no particular limitation on the lower limit for this value, considering the balance with other physical properties, the dielectric constant may be, for example, at least 2.3, or 2.4 or higher.

The dielectric loss tangent (Df) of the metal-clad laminate at 25° C. and 10 GHz is preferably not more than 0.0080, more preferably not more than 0.0012, and even more preferably 0.0011 or lower. The lower the value of the dielectric loss tangent (Df) at 25° C. and 10 GHz for the metal-clad laminate, the better, and although there is no particular limitation on the lower limit for this value, considering the balance with other physical properties, the dielectric constant may be, for example, 0.0001 or higher.

The methods used for measuring the dielectric constant (Dk) and the dielectric loss tangent (Df) of the metal-clad laminate are the same as described above for the cured product of the resin composition. The sample of the metal-clad laminate used for the measurements of the dielectric constant (Dk) and the dielectric loss tangent (Df) may be prepared by dipping the metal-clad laminate into an etching liquid to remove the metal foil from the resin cured product, and then cutting the resulting test piece from which the metal has been removed to obtain an evaluation piece of 5 cm×10 cm with a thickness of 0.2 mm. In the case of a copper-clad laminate, a 10% by mass solution of ammonium persulfate may be used as the etching liquid.

### [Printed Wiring Board]

One embodiment of the invention provides a printed wiring board having a cured product of the resin composition. Details regarding the resin composition are as described above.

In the printed wiring board, the cured product of the resin composition can be produced using the resin composition, a prepreg, a resin film, a metal-clad laminate, or a combination thereof. For example, a cured product of a prepreg may be used to produce a substrate for the printed wiring board, enabling a printed wiring board to be provided. Moreover, in another example, a metal-clad laminate may be used as the substrate for the printed wiring board, enabling a printed wiring board to be provided. Details regarding the prepreg, the resin film and the metal-clad laminate are as described above.

The printed wiring board may be either a single-layer printed wiring board or a multilayer printed wiring board.

### [Semiconductor Package]

One embodiment of the invention provides a semiconductor package having a printed wiring board and a semiconductor element. Details regarding the printed wiring board are as described above. The semiconductor package can be produced, for example, by using conventional methods to mount a semiconductor element and/or memory or the like onto a printed wiring board.

Examples of the embodiments are described below. The present invention is not limited to the following embodiments.

<1> A resin composition containing a curable prepolymer which contains a vinylbenzyl group and an indene ring and has a weight average molecular weight of 50,000 or higher.

<2> The resin composition according to <1>, wherein the curable prepolymer has a weight average molecular weight of 150,000 or higher.

<3> The resin composition according to <1> or <2>, wherein the curable prepolymer contains a structural unit having an indene ring and a vinylbenzyl group bonded directly to a carbon atom of the indene ring.

<4> The resin composition according to any one of <1> to <3>, wherein the curable prepolymer contains a structural unit derived from a vinylbenzyl compound having one to three vinylbenzyl groups and one indene ring per molecule.

<5> The resin composition according to any one of <1> to <4>, further containing a filler.

<6> A prepreg containing the resin composition according to any one of <1> to <5> or a semi-cured product of the resin composition.

<7> A resin film containing the resin composition according to any one of <1> to <5> or a semi-cured product of the resin composition.

<8> A metal-clad laminate having a cured product of the resin composition according to any one of <1> to <5>, and a metal foil.

<9> A printed wiring board having a cured product of the resin composition according to any one of <1> to <5>.

<10> A semiconductor package having the printed wiring board according to <9> and a semiconductor element.

### EXAMPLES

The present invention is described below in further detail using a series of examples, but the present invention is not limited to the following examples. The compositions and evaluation results for a series of resin compositions are shown in Table 1 to Table 6.

### [Method for Measuring Weight Average Molecular Weight (Mw)]

Weight average molecular weight values were determined using gel permeation chromatography (GPC), from a calibration curve produced using standard polystyrenes. The calibration curve was approximated as a cubic equation using a set of standard polystyrenes [TSK Standard Polystyrenes (Types A-2500, A-5000, F-20, F-80) (brand names)] manufactured by Tosoh Corporation. The GPC measurement conditions are shown below.
Apparatus: high-speed GPC device HLC-8320GPC (product name, Tosoh Corporation)
Detector: ultraviolet absorption detector UV-8320 (product name, Tosoh Corporation)
Columns: guard column: TSKgel guard column Super (HZ)-M+, columns: TSKgel SuperMultipore HZ-M (two columns), reference columns: TSKgel SuperH-RC (two columns), (all product names from Tosoh Corporation)
Column sizes: 4.6×20 mm (guard column), 4.6×150 mm (columns), 6.0× 150 mm (reference columns)
Eluent: tetrahydrofuran
Sample concentration: 10 mg/mL
Injection volume: 20 μL or 2 μL
Flow rate: 0.35 mL/minute
Measurement temperature: 40° C.

### [Preparation of Vinylbenzyl Monomer (1)]

A reaction vessel of capacity 500 mL fitted with a stirring device, a thermometer, a reflux tube and a nitrogen inlet was charged with 35.6 parts by mass of indene, 101.2 parts by mass of the chloromethylstyrene described below, 7.1 parts by mass of tetra-n-butylammonium bromide (manufactured by Kanto Chemical Co., Inc.) as a phase transfer catalyst, 0.1 parts by mass of phenothiazine as a polymerization inhibitor, and 77.6 parts by mass of toluene as a solvent, and the mixture was stirred under heat at 40° C. while nitrogen was blown into the vessel at a flow rate of 50 ml/minute.

Chloromethylstyrene [CMS-P]: manufactured by AGC Seimi Chemical Co., Ltd., a mixture of the m-isomer and the p-isomer with a m-isomer content of 50% by mass and a p-isomer content of 50% by mass.

Subsequently, 46.5 parts by mass of an aqueous solution of the basic compound described below was added dropwise over a period of 20 minutes, and stirring was continued for a further 9 hours at 60° C. The nitrogen flow was continued throughout the reaction. The temperature was then cooled to room temperature (about 25° C.), and following neutralization with a 10% aqueous solution of hydrochloric acid, the product was washed twice with pure water, the toluene was removed by distillation under reduced pressure, and the thus obtained viscous liquid was washed with methanol and then dried under vacuum, yielding a vinylbenzyl monomer (1).

Aqueous solution of basic compound: aqueous solution of sodium hydroxide with a concentration of 48% by mass, manufactured by Kanto Chemical Co., Inc.

Using ¹H-NMR analysis, the obtained vinylbenzyl monomer (1) was confirmed as a structure having vinylbenzyl groups bonded directly to the carbon atoms of the indene ring at position-1, position-3 or a combination thereof. Further, gel permeation chromatography (GPC) analysis confirmed that the vinylbenzyl monomer (1) was a mixture of compounds having two vinylbenzyl groups and a compound having three vinylbenzyl groups. In the case of the vinylbenzyl monomer having three vinylbenzyl groups, the monomer was confirmed as having two vinylbenzyl groups bonded directly to the carbon atom at position-1 of the indene ring, and one vinylbenzyl group bonded directly to the carbon atom at position-3. The weight average molecular weight (Mw) of the vinylbenzyl monomer (1) was 500. The weight average molecular weight (Mw) was measured using the method described above.

### [Production of Prepolymer (1)]

The vinylbenzyl monomer (1) obtained above was mixed with sufficient toluene to form a mixture with a solid fraction of 60% by mass. A 5 L separable flask was charged with 4,000 g of this mixture of the vinylbenzyl monomer (1) with a solid fraction of 60% by mass and 24 g of the azo-based polymerization initiator described below, and the resulting mixture was stirred at 200 rpm for one minute. Subsequently, with nitrogen flowing into the flask at a rate of 400 ml/minute, the mixture was heated to a temperature of 110° C.±10° C.

When the Mw value of the produced curable prepolymer (1) reached the target value within a range from 5,000 to 500,000, heating was halted and the reaction mixture was cooled, yielding a solution of the curable prepolymer (1) of the Mw value shown in the tables. The weight average molecular weight (Mw) was measured using the method described above.

Azo-based polymerization initiator: 2,2′-azobis(2,4,4-trimethylpentane) (VR-110 (product name) manufactured by FUJIFILM Wako Pure Chemical Corporation (10-hour half-life temperature: 110° C.)

### [Preparation of Vinylbenzyl Monomer (2)]

A reaction vessel of capacity 500 mL fitted with a stirring device, a thermometer, a reflux tube and a nitrogen inlet was charged with 35.6 parts by mass of indene, 101.2 parts by mass of the chloromethylstyrene described above, 24.1 parts by mass of α-chloro-p-xylene, 9.1 parts by mass of tetra-n-butylammonium bromide (manufactured by Kanto Chemical Co., Inc.) as a phase transfer catalyst, 0.1 parts by mass of phenothiazine as a polymerization inhibitor, and 91.6 parts by mass of toluene as a solvent, and the mixture was stirred under heat at 40° C. while nitrogen was blown into the vessel at a flow rate of 50 ml/minute.

Subsequently, 122.9 parts by mass of the aqueous solution of the basic compound described above was added dropwise over a period of 20 minutes, and stirring was continued for a further 9 hours at 60° C. The nitrogen flow was continued throughout the reaction. The temperature was then cooled to room temperature (about 25° C.), and following neutralization with a 10% aqueous solution of hydrochloric acid, the product was washed twice with pure water, the toluene was removed by distillation under reduced pressure, and the thus obtained viscous liquid was washed with methanol and then dried under vacuum, yielding a vinylbenzyl monomer (2).

Based on 1H-NMR analysis, it was evident that for the obtained vinylbenzyl monomer (2), a reaction had occurred in which a vinylbenzyl group or a methylbenzyl group had bonded to one or more of position-1 to position-3 of the indene ring. Further, gel permeation chromatography (GPC) analysis confirmed that the vinylbenzyl monomer (2) was a mixture of compounds having one introduced substituent selected from the group consisting of a vinylbenzyl group and a methylbenzyl group (mono-substituted compounds), compounds having two introduced substituents (di-substituted compounds), and compounds having three introduced substituents (tri-substituted compounds). The weight average molecular weight (Mw) of the vinylbenzyl monomer (2) was 323. The weight average molecular weight (Mw) was measured using the method described above.

### [Production of Prepolymer (2)]

The vinylbenzyl monomer (2) obtained above was mixed with sufficient toluene to form a mixture with a solid fraction of 60% by mass. A 5 L separable flask was charged with 4,000 g of this mixture of the vinylbenzyl monomer (2) with a solid fraction of 60% by mass and 24 g of the azo-based polymerization initiator described above, and the resulting mixture was stirred at 200 rpm for one minute. Subsequently, with nitrogen flowing into the flask at a rate of 400 ml/minute, the mixture was heated to a temperature of 110° C.=10° C.

When the Mw value of the produced curable prepolymer (2) reached the target value within a range from 5,000 to 500,000, heating was halted and the reaction mixture was cooled, yielding a solution of the curable prepolymer (2) of the Mw value shown in the tables. The weight average molecular weight (Mw) was measured using the method described above.

### [Preparation of Resin Compositions]

The various components shown in the tables were blended with toluene in accordance with the amounts shown in the tables, and then stirred and mixed at 25° C., thus preparing resin compositions of the examples and comparative examples, each having a solid fraction concentration of 60% by mass. In the tables, the units for the amount of each component are “parts by mass”, and in the case of a solution, means the parts by mass of the equivalent solid fraction.

The components used were as follows.
Vinylbenzyl monomer (1): the monomer produced above was used
Curable prepolymer (1): the prepolymer produced above was used
Curable prepolymer (2): the prepolymer produced above was used
Elastomer 1: a styrene-ethylene-butylene-styrene copolymer (SEBS), styrene quantity: 20% by mass, product name: MD-1648, manufactured by Kraton Corporation
Elastomer 2: a styrene-ethylene-butylene copolymer (SEB), styrene quantity: 34% by mass, product name: MD-6951, manufactured by Kraton Corporation
Silica filler: average particle size: 2 μm

### [Preparation of Prepregs]

Each of the obtained resin compositions was impregnated into and coated onto a glass cloth of thickness 0.5 mm (manufactured by Nitto Boseki Co., Ltd.) and then dried under heating at 130° C. for 4 minutes, thus yielding a prepreg with a solid fraction content derived from the resin composition of 70% by mass.

### [Preparation of Copper-Clad Laminates]

Electrolytic copper foil of thickness 18 μm (3EC-M3-VLP-18 (product name) manufactured by Mitsui Mining & Smelting Co., Ltd.) was overlaid on both sides of each of the obtained prepregs, with the matt surface of the foil facing the prepreg, and the resulting structure was then subjected to heat and compression under vacuum press conditions including a temperature of 230° C. and a pressure of 3 MPa for a period of 80 minutes, thus forming a copper-clad laminate.

### [Evaluation Methods and Measurement Methods]

Evaluations and measurements were conducted as follows. The results are shown in the tables.

### (Tackiness of Prepregs)

Each resin composition was impregnated into and coated onto a glass cloth of thickness 30 μm and then dried at 130° C. for 10 minutes, thus forming a prepreg. At this time, the procedure was conducted so that the thickness of the dried prepreg was 50 μm. Following drying, without conducting curing, the surface of the prepreg was touched with a finger, and a sensory evaluation of the tackiness was performed. The evaluation criteria were as follows. The standard used for determining an evaluation of “no tackiness” was equivalence with the prepreg of Example 1.
A: no tackiness
B: tackiness

### (Compatibility of Resin Composition)

The resin composition was placed in a transparent screw-top flask and left to stand for one hour, and the resin composition was then evaluated visually for the presence or absence of phase separation. The evaluation criteria were as shown below. Further, the resin composition was dripped into an aluminum cup, and dried and cured in a dryer at 170° C. for 30 minutes. A visual inspection was then conducted to ascertain whether or not the resin composition had separated in patches. In the examples and comparative examples for which no phase separation of the resin composition was observed, the resin did not separate into patches upon application.
A: no phase separation of the resin composition was observed
B: phase separation of the resin composition was observed

### (Moldability of Copper-Clad Laminate)

Each of the copper-clad laminates produced above was cut into a 250 mm square shape, and about 1 cm of the edges was then cut and removed. Subsequently, the copper foil on the surfaces of the copper-clad laminate was removed by etching to form an evaluation substrate. The edges and surface of the evaluation substrate were evaluated visually for the presence or absence of separation of the resin or the silica filler. Further, the evaluation substrate was also inspected visually for the presence of streaks. The evaluation criteria were as follows.
A: no streaking observed on the surface of the evaluation substrate, and no visible separation of the resin or silica filler
B: some streaking observed on the surface of the evaluation substrate, but no separation of the resin or silica filler was observed
C: separation was observed on the evaluation substrate

### (Dielectric Characteristics of Cured Product of Resin Composition)

The dielectric constant (Dk) and the dielectric loss tangent (Df) of the cured product of each resin composition was measured at 25° C. in the 10 GHz band in accordance with the SPDR method (Split Post Dielectric Resonator). A “PNA Network Analyzer N5227A” (product name) manufactured by Agilent Technologies, Inc. was used as the measurement apparatus. The sample used for measuring the dielectric constant (Dk) and dielectric loss tangent (Df) of the cured product of each resin composition was prepared by curing the resin composition to achieve a C-stage state as prescribed in JIS K 6800 (1985). Specifically, the solvent of the resin composition was removed by drying at 130° C. for 10 minutes, and the resulting resin powder was placed in a PTFE mold and press molded. The press molding conditions were the same conditions as those used in the “Preparation of Copper-Clad Laminates”, and yielded a sample of 5 cm×6 cm with a thickness of 1 cm.

TABLE 1
Compositions and Evaluation Results

| | | | Com- | Com- | Com- | Com- | Com- | Com- | Com- | Com- |
|---|---|---|---|---|---|---|---|---|---|---|
| | | | parative | parative | parative | parative | parative | parative | parative | parative |
| | | | Example | Example | Example | Example | Example | Example | Example | Example |
| | Item | Units | 1 | 2 | 3 | 4 | 5 | 6 | 7 | 8 |
| Com- | Vinylbenzyl | parts | 100 | 100 | 100 | 100 | — | — | — | — |
| position | monomer (1) | by | | | | | | | | |
| | | mass | | | | | | | | |
| | Curable | parts | — | — | — | — | 100 | 100 | 100 | 100 |
| | prepolymer (1) | by | | | | | | | | |
| | | mass | | | | | | | | |
| | Weight | — | — | — | — | — | 5,000 | 30,000 | 5,000 | 30,000 |
| | average | | | | | | | | | |
| | molecular | | | | | | | | | |
| | weight (Mw) | | | | | | | | | |
| | of curable | | | | | | | | | |
| | prepolymer (1) | | | | | | | | | |
| | Elastomer 1 | parts | — | 20 | 40 | 60 | — | — | 40 | 60 |
| | | by | | | | | | | | |
| | | mass | | | | | | | | |
| | Elastomer 2 | parts | — | — | — | — | — | — | — | — |
| | | by | | | | | | | | |
| | | mass | | | | | | | | |
| | Silica filler | parts | 200 | 270 | 300 | 350 | 200 | 200 | 200 | 200 |
| | | by | | | | | | | | |
| | | mass | | | | | | | | |
| Eval- | Tackiness of | — | B | B | B | B | B | B | B | A |
| uation | prepreg | | | | | | | | | |
| results | Compatibility | — | — | A | A | B | — | — | A | A |
| | of resin | | | | | | | | | |
| | composition | | | | | | | | | |
| | Moldability of | — | B | B | B | C | A | A | C | C |
| | copper-clad | | | | | | | | | |
| | laminate | | | | | | | | | |
| | Dielectric | — | 3.20 | 3.15 | 3.10 | 3.05 | 3.20 | 3.20 | 3.10 | 3.05 |
| | constant (Dk) | | | | | | | | | |
| | of cured product | | | | | | | | | |
| | Dielectric loss | — | 0.0012 | 0.0009 | 0.0008 | 0.0006 | 0.0012 | 0.0012 | 0.0008 | 0.0006 |
| | tangent (Df) of | | | | | | | | | |
| | cured product | | | | | | | | | |

TABLE 2
Compositions and Evaluation Results

| | | | Com- | Com- | Com- | Com- | Com- | Com- | Com- | Com- |
|---|---|---|---|---|---|---|---|---|---|---|
| | | | parative | parative | parative | parative | parative | parative | parative | parative |
| | | | Example | Example | Example | Example | Example | Example | Example | Example |
| | Item | Units | 9 | 10 | 11 | 12 | 13 | 14 | 15 | 16 |
| Com- | Vinylbenzyl | parts | 100 | 100 | 100 | 100 | — | — | — | — |
| position | monomer (1) | by | | | | | | | | |
| | | mass | | | | | | | | |
| | Curable | parts | — | — | — | — | 100 | 100 | 100 | 100 |
| | prepolymer (1) | by | | | | | | | | |
| | | mass | | | | | | | | |
| | Weight | — | — | — | — | — | 5,000 | 30,000 | 5,000 | 30,000 |
| | average | | | | | | | | | |
| | molecular | | | | | | | | | |
| | weight (Mw) | | | | | | | | | |
| | of curable | | | | | | | | | |
| | prepolymer (1) | | | | | | | | | |
| | Elastomer 1 | parts | — | 20 | 40 | 60 | — | — | 40 | 60 |
| | | by | | | | | | | | |
| | | mass | | | | | | | | |
| | Elastomer 2 | parts | — | — | — | — | — | — | — | — |
| | | by | | | | | | | | |
| | | mass | | | | | | | | |
| | Silica filler | parts | — | — | — | — | — | — | — | — |
| | | by | | | | | | | | |
| | | mass | | | | | | | | |
| Eval- | Tackiness of | — | B | B | B | B | B | B | B | A |
| uation | prepreg | | | | | | | | | |
| results | Compatibility | — | — | A | A | B | — | — | A | A |
| | of resin | | | | | | | | | |
| | composition | | | | | | | | | |
| | Moldability of | — | B | B | B | C | A | A | C | C |
| | copper-clad | | | | | | | | | |
| | laminate | | | | | | | | | |
| | Dielectric | — | 2.65 | 2.60 | 2.55 | 3.05 | 2.65 | 2.55 | 2.50 | 2.50 |
| | constant (Dk) | | | | | | | | | |
| | of cured product | | | | | | | | | |
| | Dielectric loss | — | 0.0014 | 0.0011 | 0.0009 | 0.0006 | 0.0014 | 0.0015 | 0.0009 | 0.0006 |
| | tangent (Df) of | | | | | | | | | |
| | cured product | | | | | | | | | |

TABLE 3
Compositions and Evaluation Results

| | | | Example | Example | Example | Example | Example | Example | Example | Example |
|---|---|---|---|---|---|---|---|---|---|---|
| | Item | Units | 1 | 2 | 3 | 4 | 5 | 6 | 7 | 8 |
| Com- | Curable | parts | 100 | 100 | 100 | 100 | 100 | 100 | 100 | 100 |
| position | prepolymer | by | | | | | | | | |
| | (1) | mass | | | | | | | | |
| | Weight | — | 50,000 | 100,000 | 150,000 | 300,000 | 500,000 | 150,000 | 300,000 | 150,000 |
| | average | | | | | | | | | |
| | molecular | | | | | | | | | |
| | weight (Mw) | | | | | | | | | |
| | of curable | | | | | | | | | |
| | prepolymer | | | | | | | | | |
| | (1) | | | | | | | | | |
| | Elastomer 1 | parts | — | — | — | — | — | 20 | 20 | 40 |
| | | by | | | | | | | | |
| | | mass | | | | | | | | |
| | Elastomer 2 | parts | — | — | — | — | — | — | — | — |
| | | by | | | | | | | | |
| | | mass | | | | | | | | |
| | Silica filler | parts | 200 | 200 | 200 | 200 | 200 | 270 | 270 | 300 |
| | | by | | | | | | | | |
| | | mass | | | | | | | | |
| Eval- | Tackiness of | — | A | A | A | A | A | A | A | A |
| uation | prepreg | | | | | | | | | |
| results | Compatibility | — | — | — | — | — | — | A | A | A |
| | of resin | | | | | | | | | |
| | composition | | | | | | | | | |
| | Moldability | — | A | A | A | A | A | A | A | A |
| | of | | | | | | | | | |
| | copper-clad | | | | | | | | | |
| | laminate | | | | | | | | | |
| | Dielectric | — | 3.15 | 3.20 | 3.20 | 3.20 | 3.15 | 3.15 | 3.15 | 3.10 |
| | constant (Dk) | | | | | | | | | |
| | of cured | | | | | | | | | |
| | product | | | | | | | | | |
| | Dielectric | — | 0.0011 | 0.0012 | 0.0011 | 0.0012 | 0.0012 | 0.0009 | 0.0010 | 0.0008 |
| | loss tangent | | | | | | | | | |
| | (Df) of | | | | | | | | | |
| | cured product | | | | | | | | | |

TABLE 4
Compositions and Evaluation Results

| | | | Example | Example | Example | Example | Example | Example | Example | Example | Example |
|---|---|---|---|---|---|---|---|---|---|---|---|
| | Item | Units | 9 | 10 | 11 | 12 | 13 | 14 | 15 | 16 | 17 |
| Com- | Curable | parts | 100 | 100 | 100 | 100 | 100 | 100 | 100 | 100 | 100 |
| position | prepolymer | by | | | | | | | | | |
| | (1) | mass | | | | | | | | | |
| | Weight | — | 300,000 | 150,000 | 300,000 | 150,000 | 300,000 | 150,000 | 300,000 | 150,000 | 350,000 |
| | average | | | | | | | | | | |
| | molecular | | | | | | | | | | |
| | weight (Mw) | | | | | | | | | | |
| | of curable | | | | | | | | | | |
| | prepolymer | | | | | | | | | | |
| | (1) | | | | | | | | | | |
| | Elastomer 1 | parts | 40 | 60 | 60 | — | — | — | — | — | — |
| | | by | | | | | | | | | |
| | | mass | | | | | | | | | |
| | Elastomer 2 | parts | — | — | — | 20 | 20 | 40 | 40 | 60 | 60 |
| | | by | | | | | | | | | |
| | | mass | | | | | | | | | |
| | Silica filler | parts | 300 | 350 | 350 | 270 | 270 | 300 | 300 | 350 | 350 |
| | | by | | | | | | | | | |
| | | mass | | | | | | | | | |
| Eval- | Tackiness of | — | A | A | A | A | A | A | A | A | A |
| uation | prepreg | | | | | | | | | | |
| results | Compatibility | — | A | A | A | A | A | A | A | A | A |
| | of resin | | | | | | | | | | |
| | composition | | | | | | | | | | |
| | Moldability | — | A | A | A | A | A | A | A | A | A |
| | of | | | | | | | | | | |
| | copper-clad | | | | | | | | | | |
| | laminate | | | | | | | | | | |
| | Dielectric | — | 3.10 | 3.10 | 3.05 | 3.15 | 3.15 | 3.10 | 3.10 | 3.10 | 3.10 |
| | constant (Dk) | | | | | | | | | | |
| | of cured | | | | | | | | | | |
| | product | | | | | | | | | | |
| | Dielectric | — | 0.0007 | 0.0006 | 0.0007 | 0.0010 | 0.0010 | 0.0008 | 0.0009 | 0.0007 | 0.0006 |
| | loss tangent | | | | | | | | | | |
| | (Df) of | | | | | | | | | | |
| | cured product | | | | | | | | | | |

TABLE 5
Compositions and Evaluation Results

| | | | Example | Example | Example | Example | Example | Example | Example | Example | Example |
|---|---|---|---|---|---|---|---|---|---|---|---|
| | Item | Units | 18 | 19 | 20 | 21 | 22 | 23 | 24 | 25 | 26 |
| Com- | Curable | parts | 100 | 100 | 100 | 100 | 100 | — | 100 | 100 | 100 |
| position | prepolymer | by | | | | | | | | | |
| | (1) | mass | | | | | | | | | |
| | Curable | parts | | | | | | 100 | | | |
| | prepolymer | by | | | | | | | | | |
| | (2) | mass | | | | | | | | | |
| | Weight | — | 50,000 | 100,000 | 150,000 | 300,000 | 500,000 | — | 150,000 | 300,000 | 150,000 |
| | average | | | | | | | | | | |
| | molecular | | | | | | | | | | |
| | weight (Mw) | | | | | | | | | | |
| | of curable | | | | | | | | | | |
| | prepolymer (1) | | | | | | | | | | |
| | Weight | — | — | — | — | — | — | 75,000 | — | — | — |
| | average | | | | | | | | | | |
| | molecular | | | | | | | | | | |
| | weight (Mw) | | | | | | | | | | |
| | of curable | | | | | | | | | | |
| | prepolymer (2) | | | | | | | | | | |
| | Elastomer 1 | parts | — | — | — | — | — | — | 20 | 20 | 40 |
| | | by | | | | | | | | | |
| | | mass | | | | | | | | | |
| | Elastomer 2 | parts | — | — | — | — | — | — | — | — | — |
| | | by | | | | | | | | | |
| | | mass | | | | | | | | | |
| | Silica filler | parts | — | — | — | — | — | — | — | — | — |
| | | by | | | | | | | | | |
| | | mass | | | | | | | | | |
| Eval- | Tackiness of | — | A | A | A | A | A | A | A | A | A |
| uation | prepreg | | | | | | | | | | |
| results | Compatibility | — | — | — | — | — | — | — | A | A | A |
| | of resin | | | | | | | | | | |
| | composition | | | | | | | | | | |
| | Moldability of | — | A | A | A | A | A | A | A | A | A |
| | copper-clad | | | | | | | | | | |
| | laminate | | | | | | | | | | |
| | Dielectric | — | 2.60 | 2.65 | 2.65 | 2.55 | 2.50 | 2.60 | 2.55 | 2.50 | 2.45 |
| | constant (Dk) | | | | | | | | | | |
| | of cured product | | | | | | | | | | |
| | Dielectric loss | — | 0.0013 | 0.0014 | 0.0012 | 0.0014 | 0.0014 | 0.0010 | 0.0011 | 0.0011 | 0.0009 |
| | tangent (Df) of | | | | | | | | | | |
| | cured product | | | | | | | | | | |

TABLE 6
Compositions and Evaluation Results

| | | | Example | Example | Example | Example | Example | Example | Example | Example | Example |
|---|---|---|---|---|---|---|---|---|---|---|---|
| | Item | Units | 27 | 28 | 29 | 30 | 31 | 32 | 33 | 34 | 35 |
| Com- | Curable | parts | 100 | 100 | 100 | 100 | 100 | 100 | 100 | 100 | 100 |
| position | prepolymer | by | | | | | | | | | |
| | (1) | mass | | | | | | | | | |
| | Weight | — | 300,000 | 150,000 | 300,000 | 150,000 | 300,000 | 150,000 | 300,000 | 150,000 | 300,000 |
| | average | | | | | | | | | | |
| | molecular | | | | | | | | | | |
| | weight (Mw) | | | | | | | | | | |
| | of curable | | | | | | | | | | |
| | prepolymer | | | | | | | | | | |
| | (1) | | | | | | | | | | |
| | Elastomer 1 | parts | 40 | 60 | 60 | — | — | — | — | — | — |
| | | by | | | | | | | | | |
| | | mass | | | | | | | | | |
| | Elastomer 2 | parts | — | — | — | 20 | 20 | 40 | 40 | 60 | 60 |
| | | by | | | | | | | | | |
| | | mass | | | | | | | | | |
| | Silica filler | parts | — | — | — | — | — | — | — | — | — |
| | | by | | | | | | | | | |
| | | mass | | | | | | | | | |
| Eval- | Tackiness of | — | A | A | A | A | A | A | A | A | A |
| uation | prepreg | | | | | | | | | | |
| results | Compatibility | — | A | A | A | A | A | A | A | A | A |
| | of resin | | | | | | | | | | |
| | composition | | | | | | | | | | |
| | Moldability of | — | A | A | A | A | A | A | A | A | A |
| | copper-clad | | | | | | | | | | |
| | laminate | | | | | | | | | | |
| | Dielectric | — | 2.55 | 2.50 | 2.55 | 2.65 | 2.60 | 2.55 | 2.45 | 2.50 | 2.55 |
| | constant (Dk) | | | | | | | | | | |
| | of cured | | | | | | | | | | |
| | product | | | | | | | | | | |
| | Dielectric | — | 0.0008 | 0.0006 | 0.0007 | 0.0011 | 0.0011 | 0.0009 | 0.0010 | 0.0007 | 0.0006 |
| | loss tangent | | | | | | | | | | |
| | (Df) of | | | | | | | | | | |
| | cured product | | | | | | | | | | |

As shown above, it is evident that by using a resin composition containing a curable prepolymer with a weight average molecular weight (Mw) of 50,000 or higher, the tackiness of the prepreg and the moldability of the copper-clad laminate can be improved.

### INDUSTRIAL APPLICABILITY

The resin composition according to various embodiments of the present invention can be applied, for example, as a substrate material for metal-clad laminates such as copper-clad laminates and printed wiring boards and the like used in mobile communication devices typified by smart phones, network infrastructure equipment for such devices such as base station equipment, servers and routers, and electronic equipment for which increases in signal speed and signal capacity are anticipated, such as large-scale computers.

This application is related to the subject matter disclosed in prior Japanese Application 2023-085360 filed on May 24, 2023, the entire content of which is incorporated herein by reference. It should be noted that, besides the embodiments already described above, various modifications and variations can be made in these embodiments without departing from the novel and advantageous features of the present invention. Accordingly, it is intended that all such modifications and variations are included within the scope of the appended claims.

1. A resin composition comprising a curable prepolymer which contains a vinylbenzyl group and an indene ring and has a weight average molecular weight of 50,000 or higher.

2. The resin composition according to claim 1, wherein the curable prepolymer has a weight average molecular weight of 150,000 or higher.

3. The resin composition according to claim 1, wherein the curable prepolymer contains a structural unit having an indene ring and a vinylbenzyl group bonded directly to a carbon atom of the indene ring.

4. The resin composition according to claim 1, wherein the curable prepolymer contains a structural unit derived from a vinylbenzyl compound having one to three vinylbenzyl groups and one indene ring per molecule.

5. The resin composition according to claim 1, further comprising a filler.

6. A prepreg comprising the resin composition according to claim 1 or a semi-cured product of the resin composition.

7. A resin film comprising the resin composition according to claim lor a semi-cured product of the resin composition.

8. A metal-clad laminate having a cured product of the resin composition according to claim 1, and a metal foil.

9. A printed wiring board having a cured product of the resin composition according to claim 1.

10. A semiconductor package having the printed wiring board according to claim 9 and a semiconductor element.

11. The resin composition according to claim 2, wherein the curable prepolymer contains a structural unit having an indene ring and a vinylbenzyl group bonded directly to a carbon atom of the indene ring.

12. The resin composition according to claim 2, wherein the curable prepolymer contains a structural unit derived from a vinylbenzyl compound having one to three vinylbenzyl groups and one indene ring per molecule.

13. The resin composition according to claim 2, further comprising a filler.

14. The resin composition according to claim 3, wherein the curable prepolymer contains a structural unit derived from a vinylbenzyl compound having one to three vinylbenzyl groups and one indene ring per molecule.

15. The resin composition according to claim 3, further comprising a filler.

16. The resin composition according to claim 3, wherein the curable prepolymer contains a structural unit derived from a vinylbenzyl compound having one to three vinylbenzyl groups and one indene ring per molecule.
